(19) United States
(12) Patent Application Publication
(10) Pub. No.: US 2012/0025701 A1
(43) Pub. Date: Feb. 2, 2012

(54) OLED DEVICE WITH AESTHETICAL APPEARANCE

(75) Inventor: Dietrich Bertram, Aachen (DE)

(73) Assignee: Koninklijke Philips Electronics N.V., Eindhoven (NL)

(21) Appl. No.: 13/263,462

(22) PCT Filed: Apr. 1, 2010
(86) PCT No.: PCT/IB2010/051421

§ 371 Date: Oct. 7, 2011

(30) Foreign Application Priority Data
Apr. 8, 2009 (EP) 09157570.4

(51) Int. Cl. H01L 51/52

(52) U.S. Cl. 313/512

(57) ABSTRACT

The invention relates to an OLED device (100) with a planar rigid carrier substrate (10) on which an OLED structure with electrode layers (11, 13) and an intermediate organic electroluminescent layer (12) is disposed. The device further comprises a soft frame (20) that at least partially covers the edges of the carrier substrate and/or the OLED structure. By the selection of appropriate materials, for example leather or fabrics, the frame (20) can be given an aesthetically pleasant appearance.

### FIELD OF THE INVENTION

The invention relates to an OLED device comprising a rigid carrier substrate on which an OLED (Organic Light Emitting Diode) structure is disposed.

### BACKGROUND OF THE INVENTION

The WO-2003020545 A1 discloses to attach a flexible OLED sheet to a component of a vehicle and to cover it with the decorative materials that are applied to the surface of said component.

### SUMMARY OF THE INVENTION

Based on this situation it was an object of the present invention to provide OLED devices for a broad range of applications that are both robust and aesthetically pleasant.

This problem is solved by an OLED device according to claim 1. Preferred embodiments are disclosed in the dependent claims.

The OLED device according to the invention comprises the following components:
a) A substantially planar, rigid carrier substrate. The carrier substrate will typically be transparent to allow the passage of light generated in the OLED device. It may for example consist of glass or a transparent polymer.
b) A planar OLED structure that (by definition) comprises two electrode layers between which an organic electroluminescent layer is disposed. The electrode layers and the organic electroluminescent layer are the essential components of an Organic Light Emitting Diode (OLED) as it is known in the state of the art (cf. Joseph Shinar (ed.): “Organic Light Emitting Devices, A survey”, Springer, 2004). It should be noted that the organic electroluminescent layer will typically comprise several sub-layers of different composition and functionality, and that the OLED structure may optionally comprise further layers.
c) A soft frame that at least partially covers the edges of the carrier substrate and/or of the OLED structure. The “softness” of the frame shall by definition imply that it will deform to a detectable degree when force of about 1 Newton is applied to an area of about 1 mm² of the frame surface. The aforementioned deformation may be reversible in case of an elastic frame, or permanent in case of a plastic frame. In the latter case, the permanent deformation shall however not correspond to a damage but rather be a “normal” reaction of the frame.
d) Contact elements for providing external electrical access to the electrode layers.

The described OLED device has the advantage that it can be used in many applications, because the light generating elements are arranged on a rigid carrier structure. Furthermore, the OLED device can be used in different environments, particularly in environments where an aesthetically pleasant appearance is desired. This is due to the provision of a soft frame, which allows an easy integration into such environments while at the same time providing protection of the edges of the OLED device.

Preferred materials for the soft frame of the OLED device comprise (synthetic and natural) leather, fabrics, silk, synthetic fiber, plastics, silicone, silicone-type materials, foam, foamed-up polymers, foamed-up metals, cork, wood, paper, cardboard, rubber, rubber-type materials, and/or air-filled foils. If the frame material is transparent, it can optionally also cover at least part of the light-emitting surfaces.

Preferably, the frame of the OLED device has a decorative design. This decorative design may be achieved by the choice of a particular frame material (e.g. leather) and/or by a surface structure of the frame (e.g. a particular coating, imprint, texture or the like).

In another preferred embodiment of the OLED device, the frame extends beyond the outer surface of the carrier substrate and/or of the OLED structure, wherein the term “beyond” is defined with respect to a direction perpendicular to the plane of the carrier substrate and the OLED structure. In this embodiment, the frame constitutes the highest (or lowest) component of the OLED device, which provides additional protection for the outer surfaces of the device. Moreover, the boundaries of the light emitting surfaces can be concealed with this design in an aesthetically acceptable manner.

The contact elements are needed to provide electrical access to the electrode layers in the OLED device via which the latter can be supplied with the necessary energy and/or control signals. In general, these contact elements may be arranged independently of the soft frame. This may for example be the case for a hook that is attached to the OLED device and electrically connected to an electrode layer, said hook functioning like a plug, thus providing both mechanical and electrical contact. Another example of a contact element is a magnet that can both mechanically fix the OLED device and provide electrical access to an electrode layer.

Still another example is a hook-and-loop fastener (“Velcro® fastener”) made from electrically conductive materials, which can also provide both mechanical fixation and electrical contact.

Preferably, the contact elements (e.g. the aforementioned hook, magnet, or hook-and-loop fastener) are completely or at least partially disposed in the frame. This is particularly the case if the frame completely encompasses the edges of the carrier substrate and/or the OLED structure.

The contact elements may for example comprise a hole in the frame which leads to some electrical terminals that are electrically connected to the electrode layers. The hole can then function like a socket into which a plug can be inserted.

The contact elements may optionally comprise wires that are connected to the electrode layers. By such wires, contact terminals can be disposed at any convenient location of the OLED device.

According to another embodiment, the contact elements may comprise a feedthrough that is disposed in the frame. Such a feedthrough may for example be realized by a rivet that is connected by wires to the electrode layers of the OLED structure.

According to a further development of the invention, the aforementioned feedthrough may additionally be designed as a mechanical fastener for the OLED device. In case of rivets being used as a feedthrough, screws can for example be used to mechanically fix the OLED device.

### BRIEF DESCRIPTION OF THE DRAWINGS

These and other aspects of the invention will be apparent from and elucidated with reference to the embodiment(s) described hereinafter. These embodiments will be described by way of example with the help of the accompanying drawing in which:

FIG. 1 schematically illustrates a section through an OLED device according to the present invention.

### DETAILED DESCRIPTION OF EMBODIMENTS

OLED lamps are very suitable for decorative applications, which can be very diverse, reaching from art objects over semi functional items, like name plates or name-cards, to decorative lighting solutions, often based on multiple OLEDs. Known OLED panels consist of coated glass plates, glued to a protective glass cover, which gives a rather slim but fragile glass object, emitting light from one surface. Contacting of the glass plate as well as protecting the OLED against mechanical damages is a rather delicate issue and in many cases not solved with known systems. Especially, where the application is of a decorative manner, the requirements on the aesthetic value of the protective cover can be very demanding.

To combine an aesthetic valuable solution with the technically necessary protection, it is proposed here to frame an OLED panel with a border made of a soft and aesthetically valuable material, like e.g. leather around the edges of the OLED panel. This border or frame usually also encompasses electrical connections, which could be realized by simply making holes in the frame or by attaching wires to the OLED which can be taken through the frame. Alternatively, the frame can be combined with rivets, hooks, or magnets, which are fixed in the frame and which are contacted internally with wires to the OLED panel and serve as external contact.

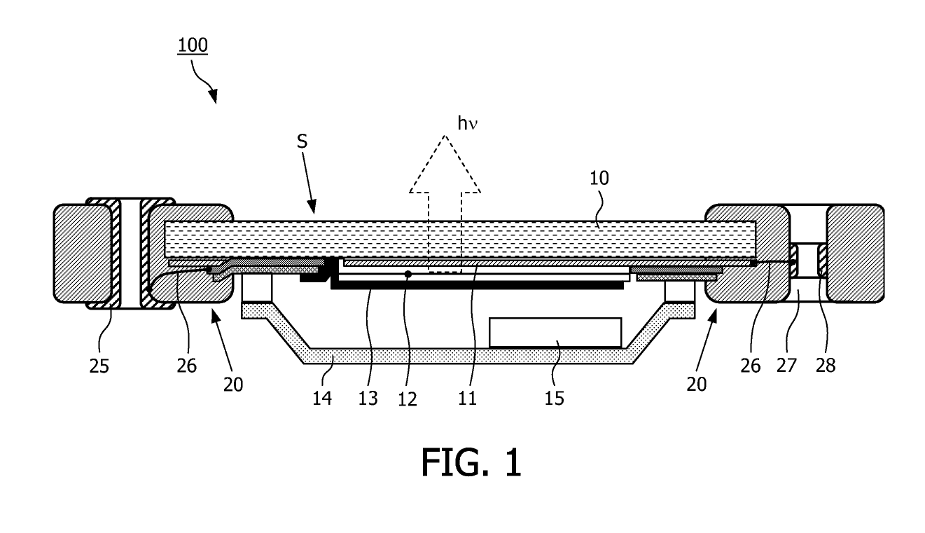

A concrete realization of an OLED device 100 according to the aforementioned concepts is illustrated in FIG. 1. The OLED device 100 comprises the following components:
A planar rigid carrier substrate 10, for example a (front-) glass plate.
A first electrode layer 11. This layer will typically be transparent and be made from indium tin oxide (ITO). During operation, it will usually serve as an anode.
An organic electroluminescent (multi-)layer 12, for example comprising small molecules (smOLED) or polymers (Polymer-OLED).
A second electrode 13, which may be transparent or not, and usually serves as a cathode during operation.
A cover 14 that provides mechanical protection of the back side and sealing of the OLED device.
A getter 15 for maintaining a low water vapor and/or oxygen concentration atmosphere inside the housing.
A frame 20 that completely encircles the edges of the carrier substrate 10 and the OLED structure with the electrode layers 11, 13 and the organic electroluminescent layer 12, and that extends beyond (i.e. above) the upper surface S of the OLED structure and the carrier substrate.

The frame material may be attached to the carrier substrate 10 and/or the OLED structure by formfitting or, preferably, materially bonded. The latter may for example be achieved by gluing.

The frame 20 is made of a soft material. In one edge of the frame 20 (right side in the Figure), a hole 27 is provided with a socket 28 that is electrically connected by a wire 26 to the electrode layer 11. In the opposite edge of the frame 20 (left side in the Figure), a rivet 25 is provided that is within the frame 20 electrically connected by a wire 26 to the electrode layer 13. The rivet 25, the hole 27, the socket 28, and the wires 26 serve as contact elements that provide electrical access to the electrode layers (it should be noted that both a rivet and a hole in one and the same OLED device 100 are provided primarily for illustrative purposes; usually, all electrical contact elements would preferably be of one type, e.g. two rivets).

In a further embodiment, the rivets can be formed to become a mechanical fixation of the framed OLED panel 100, which at the same time provides electrical contacts, like e.g. buttons. Other materials, like e.g. silicone containing materials, different types of fabric, soft plastics or the like can be used as materials for the frame 20.

Furthermore, the second electrode 13 and the cover 14 may be transparent to make the whole OLED panel 100 transparent. Of course many other OLED designs can be used, too, for example non-transparent OLEDs or OLEDs with a thin-film encapsulation.

Moreover, the frame 20 may also cover (at least partially) the back side of the OLED panel 100 (not shown). If it is a transparent material, e.g. silicon, it may also extend over the front side (surface S) of the panel.

In summary, an OLED device according to the present invention is characterized by one or more of the following features:
It is equipped with a protective frame made of aesthetic valuable material, such as leather, fabrics, silicone type materials or the like.
The frame has holes through which the contacts to the OLED are supplied with electrical current.
It has wired contacts, which are passed through holes in the frame material to provide electrical contact to the OLED structure.
The frame material has electrical feedthroughs (e.g. rivets), which are connected to the OLED structure by means of wires, spring contacts or the like and which connect through the feedthroughs to external power sources.
The electrical feedthroughs are also used for mechanical fixation of the OLED panel.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. An OLED device, comprising
a) a planar rigid carrier substrate;
b) a planar OLED structure that is disposed on the carrier substrate and that comprises two electrode layers and an intermediate organic electroluminescent layer;
c) a soft frame that at least partially covers the edges of the carrier substrate and/or of the OLED structure; and
d) contact elements for providing electrical access to the electrode layers.

2. The OLED device according to claim 1, wherein the frame comprises a material selected from the group consisting of synthetic leather, natural leather, fabrics, silk, synthetic fiber, plastics, silicone, silicone-type material, foam, foamed-up polymers, foamed-up metals, cork, wood, paper, cardboard, rubber, rubber-type materials, and/or air-filled foils.

3. The OLED device according to claim 1, wherein the frame has a decorative design.

4. The OLED device according to claim 1, wherein the frame extends beyond the outer surface of the carrier substrate and/or the OLED structure.

5. The OLED device according to claim 1, wherein the contact elements are at least partially disposed in the frame.

6. The OLED device according to claim 1, wherein the contact elements comprise a hole in the frame.

7. The OLED device according to claim 1, wherein the contact elements comprise wires that are connected to the electrode layers.

8. The OLED device according to claim 1, wherein the contact elements comprise a feedthrough disposed in the frame.

9. The OLED device according to claim 8, wherein the feedthrough comprises a mechanical fastener.

10. The OLED device according to claim 1, wherein the contact elements comprise a rivet, a hook, a magnet, and/or a hook-and-loop fastener.

11. The OLED device according to claim 1, wherein the carrier substrate is transparent.
